(19) United States
(12) Patent Application Publication
(10) Pub. No.: US 2025/0105047 A1
(43) Pub. Date: Mar. 27, 2025

(54) SEMICONDUCTOR ELEMENT TRANSFER APPARATUS AND TRANSFER METHOD USING THE SAME

(71) Applicants: HYUNDAI MOTOR COMPANY, Seoul (KR); KIA CORPORATION, Seoul (KR)

(72) Inventors: Tae Woo KWANG, Hanam-si (KR); Young Jin SON, Suwon-si (KR)

(21) Appl. No.: 18/434,751

(22) Filed: Feb. 6, 2024

(30) Foreign Application Priority Data
Sep. 21, 2023 (KR) 10-2023-0126127

(51) Int. Cl. H01L 21/683; H01L 21/67

(52) U.S. Cl. CPC H01L 21/6838; H01L 21/67115; H01L 21/67248

(57) ABSTRACT

An apparatus for transferring a semiconductor element includes a support base, a plurality of adsorption portions provided on a lower surface of the support base, a vacuum portion coupled to the support base and providing vacuum to the plurality of adsorption portions, and a heating portion coupled to the support base and heating a semiconductor element to be fixed to the plurality of adsorption portions, wherein the heating portion includes a heating plate disposed on the lower surface of the support base, and the heating plate is arranged to be surrounded by the plurality of adsorption portions on the lower surface of the support base.

### CROSS-REFERENCE TO RELATED APPLICATION(S)

This application claims benefit of priority to Korean Patent Application No. 10-2023-0126127, filed on Sep. 21, 2023, in the Korean Intellectual Property Office, the disclosure of which is incorporated herein by reference in its entirety.

### TECHNICAL FIELD

The present disclosure relates to a semiconductor element transfer apparatus and a transfer method using the same, and more particularly, to a transfer apparatus that may apply heat to a semiconductor element in a non-contact manner during a transfer process of a semiconductor element and a transfer method using the same.

### BACKGROUND

Semiconductor elements s manufactured through a semiconductor manufacturing process may be determined to be good or defective through an electrical test process. This test process may be performed using a tester providing inspection signals, and during this process, semiconductor elements may be transferred through a transfer apparatus that picks up or places the semiconductor elements.

In some cases, when a semiconductor element is transferred between multiple processes through a transfer apparatus, a temperature of the semiconductor element may drop during the transfer process. Specifically, if a semiconductor element is transferred using a transfer apparatus, while testing in a high temperature environment, the temperature of the semiconductor element may drop and the temperature of the semiconductor element should be raised again, which may increase process time and reduce efficiency.

### SUMMARY

An aspect of the present disclosure is to provide a semiconductor element transfer apparatus capable of stably vacuum-adsorbing a semiconductor element using a plurality of adsorption portions to prevent and/or reduce warpage of the semiconductor element, and at the same time, maintaining and/or increasing the temperature of the semiconductor element by applying heat to the semiconductor element during the transfer process.

According to an aspect of the present disclosure, an apparatus for transferring a semiconductor element includes: a support base; a plurality of adsorption portions provided on a lower surface of the support base; a vacuum portion coupled to the support base and providing vacuum to the plurality of adsorption portions; and a heating portion coupled to the support base and heating a semiconductor element to be fixed to the plurality of adsorption portions, wherein the heating portion includes a heating plate disposed on the lower surface of the support base, and the heating plate is arranged to be surrounded by the plurality of adsorption portions on the lower surface of the support base.

The heating plate may be spaced apart from the semiconductor element by a specified distance while the semiconductor element is adsorbed to the plurality of adsorption portions.

Based on the lower surface of the support base, the heating plate may be located to be lower than the plurality of adsorption portions by a specified height.

The heating portion may be connected to the support base through at least a portion of the support base so that the heating plate is exposed externally from the lower surface of the support base.

The heating portion may further include a main body provided with the heating plate at a lower portion thereof, and at least a portion of the main body passes through the support base.

The heating portion may include an infrared heater.

The heating plate may be disposed in a center of the lower surface of the support base, and the plurality of adsorption portions may be provided as three or more adsorption portions and surround the heating plate.

The plurality of adsorption portions may be arranged to be spaced apart from each other and include a first adsorption portion, a second adsorption portion, a third adsorption portion, and a fourth adsorption portion surrounding the heating plate.

The plurality of adsorption portions may be arranged so that the first adsorption portion, the second adsorption portion, the third adsorption portion, and the fourth adsorption portion are symmetrical, based on the heating plate.

Each of the first adsorption portion, the second adsorption portion, the third adsorption portion, and the fourth adsorption portion may be disposed between an edge portion of the lower surface of the support base and an edge portion of the heating plate.

The plurality of adsorption portions may be formed of a flexible material.

Each of the plurality of adsorption portions may include an adsorption hole, and the vacuum portion may be connected to the adsorption hole of each of the plurality of adsorption portions by passing through the support base and provides vacuum to the adsorption hole.

The apparatus may further include a camera unit connected to any one of the support base and the heating portion, wherein the camera unit may capture at least one of a video and an image of the semiconductor element.

The apparatus may further include: a connection portion connecting the camera unit to any one of the support base and the heating portion.

In an operation of vacuum-adsorbing the semiconductor element, the semiconductor element transfer apparatus may be configured to operate the heating portion, while moving toward the semiconductor element.

According to another aspect of the present disclosure, a method of transferring a semiconductor element includes: an operation of aligning a transfer apparatus including a plurality of adsorption portions with a semiconductor element and lowering the transfer apparatus toward the semiconductor element; an operation of vacuum-adsorbing the semiconductor element to the plurality of adsorption portions and transferring the semiconductor element; and an operation of disposing the semiconductor element in a transfer position, releasing vacuum adsorption, and raising the transfer apparatus, wherein, in the operation of lowering the transfer apparatus toward the semiconductor element, a heating portion provided in the transfer apparatus operates to correspond to a temperature condition for the semiconductor element.

The transfer apparatus may further include a camera unit, wherein the method may further include: an operation of aligning the semiconductor element and the camera unit and imaging the semiconductor element using the camera unit.

The operation of imaging the semiconductor element may be performed at least one of before the operation of lowering the transfer apparatus to vacuum-adsorb the semiconductor element and after the operation of releasing the vacuum adsorption of the semiconductor element and raising the transfer apparatus.

The transfer apparatus may further include a support base on which the plurality of adsorption portions are arranged on a lower surface of the support base, and the heating portion may include a heating plate disposed to be surrounded by the plurality of adsorption portions on the lower surface of the support base.

In the operation of vacuum-adsorbing the semiconductor element and transferring the semiconductor element, the semiconductor element may be in close contact with the plurality of adsorption portions and may be spaced apart from the heating plate at a predetermined distance.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a plan perspective view showing an example of a transfer apparatus.

FIG. 2 is a bottom perspective view showing the transfer apparatus.

FIG. 3 is a side view showing the transfer apparatus.

FIG. 4 is a bottom view showing the transfer apparatus.

FIG. 5 is a view illustrating an example operation of transferring a semiconductor element using the transfer apparatus.

FIG. 6 is a view illustrating an example operation of transferring a semiconductor element using an example of a transfer apparatus.

### DETAILED DESCRIPTION

The present disclosure may be modified variably and may have various exemplary implementations, particular examples of which will be illustrated in drawings and described in detail. However, it is to be understood that the present disclosure is not limited to a specific disclosed form, but includes all modifications, equivalents, and substitutions without departing from the scope and spirit of the present disclosure.

Hereinafter, one or more exemplary implementations of the present disclosure will be described in detail with reference to the accompanying drawings.

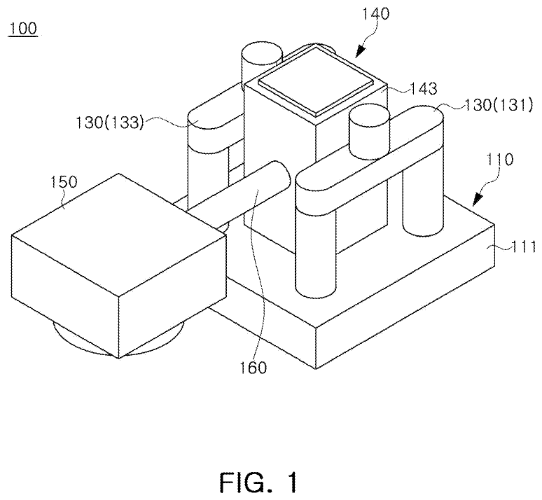

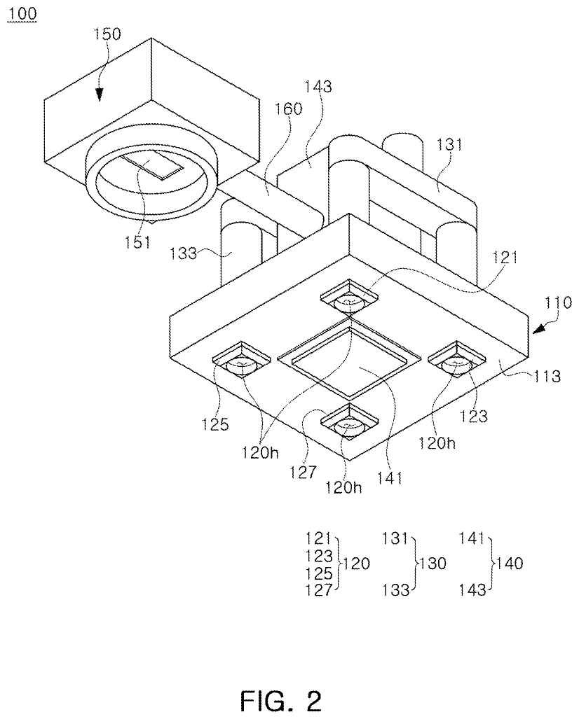

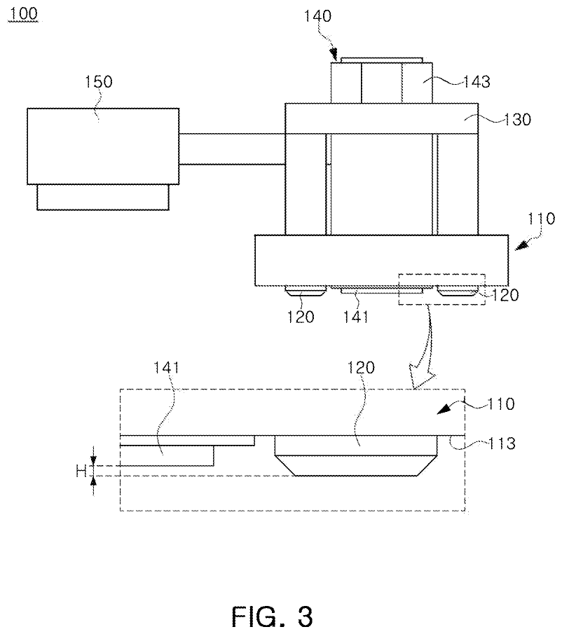

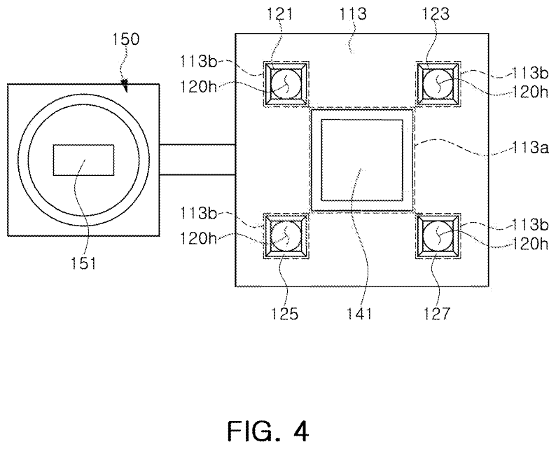

FIG. 1 is a plan perspective view showing an example of a transfer apparatus 100. FIG. 2 is a bottom perspective view of the transfer apparatus 100. FIG. 3 is a side view of the transfer apparatus 100. FIG. 4 is a bottom view of the transfer apparatus 100.

In some implementations, referring to FIGS. 1 to 4, the transfer apparatus 100 can be configured to transfer a semiconductor element, while applying heat to the semiconductor element, so that a predetermined temperature may be maintained during a process of transferring the semiconductor element (e.g., a semiconductor chip).

The semiconductor element transfer apparatus 100 according to an exemplary implementation may include a support base 110, an adsorption portion 120, a vacuum portion 130, a heating portion 140, a camera unit 150, and a connection portion 160.

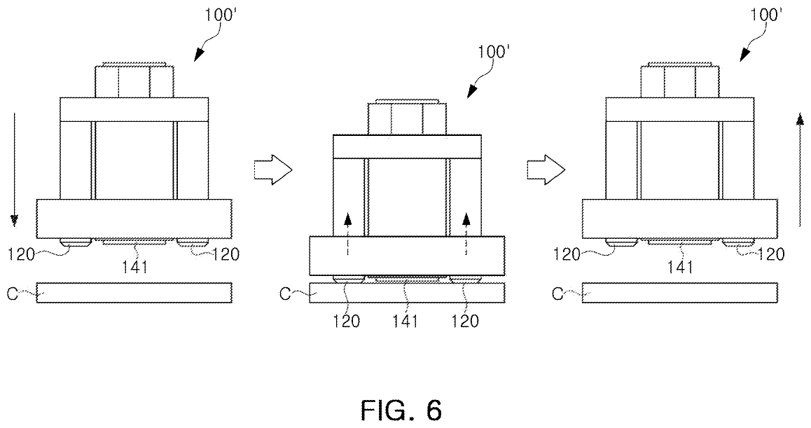

However, the structure of the transfer apparatus 100 is not limited to the exemplary implementations shown in FIGS. 1 to 4, and according to various exemplary implementations, the transfer apparatus 100 may not include the camera unit 150 and the connection portion 160 (e.g., refer to a transfer apparatus 100′ in FIG. 6).

The support base 110 may support other components included in the transfer apparatus 100. For example, the support base 110 is a component to which the adsorption portion 120, the vacuum portion 130, and the heating portion 140 may be connected and/or coupled, and may have a structure to which the adsorption portion 120, the vacuum portion 130, and the heating portion 140 may be connected and/or coupled. According to various exemplary implementations, the support base 110 may be referred to as a support plate or a support frame. The support base 110 may be formed of a heat-resistant material to withstand the heat generated by the heating portion 140.

The support base 110 may include a lower surface 113 on which the adsorption portion 120 and the heating plate 141 (or hot plate) of the heating portion 140 are disposed and an upper surface 111 facing in the opposite direction of the lower surface 113. The support base 110 may have a predetermined thickness. Inside the support base 110, a space may be provided in which at least a portion of the heating portion 140 may be disposed so that the heating plate 141 is exposed to the lower surface 113 of the support base 110. In addition, a space in which at least a portion of the vacuum portion 130 may be disposed to be connected to the adsorption portion 120 may be provided inside the support base 110.

At least a portion of the heating portion 140 and the vacuum portion 130 may be disposed on the upper surface 111 of the support base 110. For example, the heating portion 140 and the vacuum portion 130 may be provided to extend or protrude from the upper surface 111 of the support base 110.

The lower surface 113 of the support base 110 may include an adsorption region 113b in which the adsorption portion 120 is disposed and a heating region 113a in which the heating portion 140 (i.e., the heating plate 141) is disposed. For example, the adsorption region 113b may be defined as a plurality of regions in which the plurality of adsorption portions 120 are disposed and exposed from the lower surface 113 of the support base 110, and the heating region 113a may be defined as a region of the lower surface 112 of the support base 110. In which the heating plate 141 is disposed and exposed. The heating region 113a may be surrounded by a plurality of adsorption regions 113b. For example, the heating region 113a may be formed in the central region of the lower surface 113 of the support base 110, and the plurality of adsorption regions 113b may be formed in the corner region or the edge region of the lower surface 113 of the support base 110 to surround the heating region 113a.

According to the exemplary implementation shown in FIG. 4, the support base 110 may have a square shape, the heating region 113a may be formed in the center of the lower surface 113 of the support base 110, and four adsorption regions 113b may be located at the edge to be located between four corners of the support base 110 and the four corners of the heating region 113a. The number and position of the adsorption regions 113b are determined to correspond to the number and position of the adsorption portions 120. However, the shape of the support base 110 and the number and/or position of the adsorption regions 113b are not limited to the illustrated exemplary implementation.

The adsorption portion 120 may vacuum-adsorb the semiconductor element. The adsorption portion 120 may be provided on the lower surface 113 of the support base 110. An adsorption hole 120h for vacuum adsorption of the semiconductor element may be formed in the adsorption portion 120. The adsorption hole 120h may be formed through the central region of the adsorption portion 120. The adsorption portion 120 may be in contact with the semiconductor element. The adsorption portion 120 may be formed of flexible rubber or silicone resin to absorb shock applied to the semiconductor element during the process of vacuum-adsorbing the semiconductor element. However, the material of the adsorption portion 120 is not limited to the examples mentioned above.

The adsorption hole 120h of the adsorption portion 120 may be connected to the vacuum portion 130 through the support base 110. The adsorption portion 120 may be provided so that a vacuum is formed in the adsorption hole 120h by the vacuum portion 130. A predetermined through-hole may be formed in the lower surface 113 of the support base 110 to connect the adsorption hole 120h and the vacuum portion 130. For example, the adsorption hole 120h may be in fluid communication with at least a portion of the vacuum portion 130 through the through-hole formed in the support base 110.

The adsorption portion 120 may be provided in plural. For example, the adsorption portion 120 may be configured as four adsorption portions 120 including a first adsorption portion 121, a second adsorption portion 123, a third adsorption portion 125, and a fourth adsorption portion 127. The four adsorption portions 120 may be provided at the edges and/or corners of the lower surface 113 of the support base 110. Accordingly, when picking up and/or transferring the semiconductor element, warpage of the semiconductor element may be prevented and the semiconductor element may be stably adsorbed. The plurality of adsorption portions 120 may be formed in positions adjacent to the edges and/or corners of the support base 110 and symmetrical with respect to the center of the support base 110, so that even when the area of the semiconductor element has a size equal to or greater than a predetermined size, the semiconductor element may be stably vacuum-adsorbed. For example, the plurality of adsorption portions 120 may be spaced apart from the center of the support base 110 by the same distance.

In some implementations, the four adsorption portions 120 may be arranged to partially surround the heating plate 141 of the heating portion 140. The four adsorption portions 120 may be arranged in positions symmetrical, based on the heating plate 141. For example, based on FIG. 4, the first adsorption portion 121, the second adsorption portion 123, the third adsorption portion 125, and the fourth adsorption portion 127 may be arranged in positions at the same distance from the center of the heating plate 141 and spaced apart by the same distance. According to this, in the process of transferring the semiconductor element, the four adsorption portions 120 may vacuum-adsorb the edge portions of the semiconductor element and the heating plate 141 may apply heat to the center portion of the semiconductor element, and thus, since the surface area of the semiconductor element to which heat is transferred is large, heat may be transferred effectively.

In some implementations, the four adsorption portions 120 may be arranged between the four corners of the heating plate 141 and the four corners of the lower surface 113 of the support base 110. However, the present disclosure is not limited thereto, and according to various exemplary implementations, the four adsorption portions 120 may be disposed between the four edges of the heating plate 141 and the four edges of the lower surface 113 of the support base 110. Here, the corners indicate vertices of the heating plate 141 and the lower surface 113, which have a square shape, and the edges indicate the sides of the heating plate 141 and the lower surface 113, which have a square shape.

The exemplary implementation shown in FIGS. 1 to 4 illustrates an exemplary implementation among various exemplary implementations of the present disclosure, and the number and/or position of the adsorption portions 120 are not limited to the illustrated exemplary implementation. For instance, the plurality of adsorption portions 120 may be configured to be five or more or less than four so as to partially surround the heating plate 141 on the lower surface 113 of the support base 110. For example, in order to stably adsorb the semiconductor element, in some implementations, three or more adsorption portions 120 may be provided, but an exemplary implementations in which less than three adsorption portions 120 are provided is not excluded.

In addition, the shapes of the support base 110 and the heating plate 141 are not limited to the illustrated exemplary implementation. According to various exemplary implementations, the lower surface 113 of the support base 110 and/or the heating plate 141 may have a shape of polygon, other than a circle, oval, or square. Even in this case, the plurality of adsorption portions 120 may be arranged to surround the heating plate 141 on the lower surface 113 of the support base 110.

The vacuum portion 130 may provide vacuum to the adsorption portion 120 so that the semiconductor element may be adsorbed to the adsorption portion 120. For example, the vacuum portion 130 may adsorb the semiconductor element to the adsorption portion 120 or release the adsorption by forming or removing vacuum in or from the adsorption hole 120h of the adsorption portion 120. The vacuum portion 130 may include a vacuum pipe and a vacuum pump. For example, the vacuum portion 130 illustrated in FIGS. 1 to 4 is a vacuum pipe, and a vacuum pump may be connected to the vacuum pipe to provide a vacuum (or reduced pressure) to the vacuum pipe. The vacuum pipe may be connected to the adsorption portion 120, and vacuum (or reduced pressure) provided to the vacuum pipe through the vacuum pump may be provided to the adsorption hole 120h of the adsorption portion 120.

The vacuum portion 130 may be connected to the adsorption portion 120 through the support base 110. For example, at least a portion of the vacuum portion 130 may vertically pass through the upper surface 111 and the lower surface 113 of the support base 110. The vacuum portion 130 may communicate with the adsorption hole 120h of the adsorption portion 120. The vacuum portion 130 may form vacuum in the vacuum pipe connected to and/or in communication with the adsorption hole 120h to provide vacuum to the adsorption hole 120h.

The vacuum portion 130 may include a first vacuum portion 131 for providing vacuum to the first adsorption portion 121 and the second adsorption portion 123 and a second vacuum portion 133 for providing vacuum to the third adsorption portion 125 and the fourth adsorption portion 127. However, the configuration of the vacuum portion 130 is not limited to the illustrated exemplary implementation, and the first vacuum portion 131 and the second vacuum portion 133 may be formed integrally.

The heating portion 140 may be connected to and fixed to the support base 110. The heating portion 140 may include the main body 143 and the heating plate 141 provided below the main body 143. The heating portion 140 may be connected and/or coupled to the support base 110 so that the heating plate 141 is disposed on the lower surface 113 of the support base 110. For example, the heating portion 140 may be connected to the support base 110 such that at least a portion of the main body 143 passes through the support base 110 to be coupled and the heating plate 141 is exposed externally from the lower surface 113 of the support base 110.

The heating plate 141 of the heating portion 140 may be provided so that at least a portion of the heating plate 141 is surrounded by a plurality of adsorption portions 120 on the lower surface 113 of the support base 110. For example, when the lower surface 113 of the support base 110 is viewed, the heating plate 141 may be located at the center of the lower surface 113 and surrounded by a plurality of adsorption portions 120.

The heating portion 140 may apply heat to the semiconductor element in a non-contact manner. As shown in FIG. 3, the heating plate 141 may be located to be lower than the adsorption portion 120 by a specified height H based on the lower surface 113 of the support base 110. For example, the heating plate 141 may be disposed at a first height from the lower surface 113 of the support base 110, and the adsorption portion 120 may be disposed at a second height higher than the first height from the lower surface 113 of the support base 110. Accordingly, while the semiconductor element C is vacuum-adsorbed to the adsorption portion 120, the heating plate 141 may be spaced apart from the semiconductor element by approximately a difference H between the second height and the first height. Through this, since the heating plate 141 does not directly contact the semiconductor element, damage to the semiconductor element may be reduced or prevented.

The heating portion 140 may include an infrared heater. For example, the heating portion 140 using the infrared heater may include a plurality of infrared lamps and may apply heat to a semiconductor element using infrared light output from the infrared lamps. For example, the heating portion may be a far-infrared heater and may be provided to emit far-infrared rays in a wavelength range of about 5 to 25 μm. However, the type of heating portion 140 is not limited to infrared heaters, and may be provided using various heating units that may apply heat without directly contacting the semiconductor element.

The camera unit 150 may image the semiconductor element. For instance, the camera unit 150 may include a camera or an imaging sensor. The camera unit 150 may capture a video and/or images of the semiconductor element before and after the semiconductor element is transferred in order to inspect the exterior of the semiconductor element. According to various exemplary implementations, the camera unit 150 may be connected to an analysis unit (e.g., a processor, a controller, a circuit), and the analysis unit may analyze and determine whether the semiconductor element is defective or damaged based on the video and/or image information transmitted from the camera unit 150. The camera unit 150 may be provided in the transfer apparatus 100 and may be connected to the heating portion 140 or the support base 110 through the connection portion 160. The camera unit 150 may include one or more lenses 151.

The connection portion 160 may connect the camera unit 150 and the heating portion 140. For example, the connection portion 160 may extend from the camera unit 150 and be connected to the main body 143 of the heating portion 140. However, the portion to which the connection portion 160 is connected is not limited to the main body 143 of the heating portion 140. According to various exemplary implementations, the connection portion 160 may extend from the camera unit 150 and be connected to the support base 110. The connection portion 160 may have a space therein in which wiring, etc. may be disposed.

In some examples, the transfer apparatus 100 may be connected to a driving unit and driven by the driving unit. The driving unit may drive the transfer apparatus 100 so that the semiconductor element may be transferred between processes through the transfer apparatus 100. For example, in order to vacuum-adsorb and move the semiconductor element through the transfer apparatus 100, the driving unit may raise or lower the transfer apparatus 100 in a vertical direction or move the transfer apparatus 100 in a horizontal direction. In addition, according to various exemplary implementations, the driving unit may be included as a component of the transfer apparatus 100.

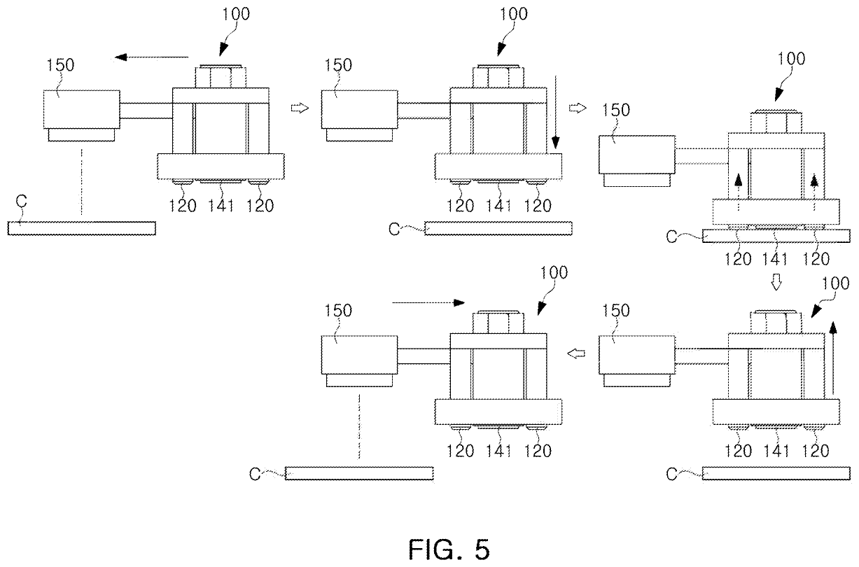

FIG. 5 is a view illustrating an operation of transferring a semiconductor element C using the transfer apparatus 100.

Referring to FIG. 5, the transfer apparatus 100 may transfer the semiconductor element C, while maintaining the semiconductor element C at a target temperature, by continuously applying heat to the semiconductor element C in the process of transferring the semiconductor element C.

The semiconductor element C transferred through the transfer apparatus 100 may be a power semiconductor element or a power semiconductor chip provided in a power module. For example, the transfer apparatus 100 may maintain the power semiconductor at a predetermined temperature, while reducing and/or preventing warpage of the power semiconductor, when transferring the power semiconductor having a relatively large area compared to a system semiconductor. However, a transfer target of the transfer apparatus 100 is not limited to power semiconductors, and various types of semiconductor elements and semiconductor chips may be the transfer target.

As shown in FIG. 5, the operation or method of transferring the semiconductor element C through the transfer apparatus 100 may include an operation of aligning the semiconductor element C and the camera unit 150 and first imaging the semiconductor element C using the camera unit 150; an operation of aligning the semiconductor element C and the adsorption portion 120 and lowering the transfer toward the semiconductor element C; an apparatus 100 operation of vacuum-adsorbing and transferring a semiconductor element C; an operation of disposing the semiconductor element C in a transfer position, releasing the vacuum adsorption, and raising the transfer apparatus 100; and an operation of aligning the semiconductor element

C and the camera unit 150 and secondly imaging the semiconductor element C using the camera unit 150. FIG. 5 illustrates the aforementioned operations in clockwise order.

In the operation of aligning the semiconductor element C and the camera unit 150 and first imaging the semiconductor element C using the camera unit 150, a primary inspection is performed on the exterior by imaging the semiconductor element C before the semiconductor element C is transferred. Results of the first imaging may be compared with results of the second imaging later and used to determine whether damage or burnout occurred in the semiconductor element C during transfer.

In the operation of aligning the semiconductor element C and the adsorption portion 120 and lowering the transfer apparatus 100 toward the semiconductor element C, the semiconductor element C and the adsorption portion 120 are aligned by horizontally moving at least one of the semiconductor element C and the transfer apparatus 100. In the process of lowering the transfer apparatus 100, the heating plate 141 is pre-heated by operating the heating portion 140 to correspond to a temperature condition. Since heat may be applied to the semiconductor element C at the same time as vacuum adsorption of the semiconductor element C, heating and/or temperature maintenance of the semiconductor element C may be efficiently performed.

In the operation of vacuum-adsorbing and transferring the semiconductor element C, vacuum is provided to the adsorption portion 120 through the vacuum portion 130 to vacuum-adsorb the semiconductor element C. At this time, the semiconductor element C is in close contact with the adsorption portion 120 but is spaced apart from the heating plate 141 by a predetermined distance (e.g., about 1 mm), so that the semiconductor element C is not in direct contact with the heating plate 141 and heat is applied indirectly., as shown in FIGS. 2 and 4, the semiconductor element C is picked up by a plurality of adsorption portions 120 (e.g., three or more adsorption portions), so that warpage of the semiconductor element C may be prevented or reduced.

In the operation of disposing the semiconductor element C in the transfer position, releasing the vacuum adsorption and raising the transfer apparatus 100, the semiconductor element C is disposed in a predetermined position by moving the transfer apparatus 100, vacuum provision (vacuum formation) by the vacuum portion 130 is stopped, and vacuum adsorption of the semiconductor element C is then released. At the same time as releasing the vacuum adsorption, the operation of the heating portion 140 is stopped.

In the operation of aligning the semiconductor element C and the camera unit 150 and secondly imaging the semiconductor element C using the camera unit 150, the semiconductor element C and the camera unit 150 are aligned by horizontally moving at least one of the semiconductor element C and the transfer apparatus 100. After the transfer of the semiconductor element C is completed, the semiconductor element C is imaged to conduct a secondary inspection of the exterior, and compared with the results of the first imaging to determine whether any damage or burnout occurred to the semiconductor element C during transfer.

The details described above regarding the operation of transferring the semiconductor element C through the transfer apparatus 100 are an example, and at least one operation may be omitted or added according to various exemplary implementations. For example, in the operation of transferring the semiconductor element C, the operation of first imaging the semiconductor element C using the camera unit 150 before transfer of the semiconductor element C may be excluded, and imaging may be performed after the transfer is completed, and based on the results, the exterior of the semiconductor element C may be inspected. For another example, in the operation of transferring the semiconductor element C, only the operation of first imaging the semiconductor element C using the camera unit 150 is performed before the transfer of the semiconductor element C, and the operation of secondly imaging the semiconductor element C using the camera unit 150 after the transfer may be excluded.

FIG. 6 is a view illustrating an operation of transferring a semiconductor element C using a transfer apparatus 100′, different from the transfer apparatus 100 of FIG. 5.

FIG. 6 illustrates an operation of transferring the semiconductor element C using the transfer apparatus 100′ in which the camera unit 150 is omitted, compared to the transfer apparatus 100 according to the exemplary implementation shown in FIG. 5.

Referring to FIG. 6, according to various exemplary implementations of the present disclosure, the transfer apparatus 100′ may be provided to have a structure without the camera unit 150 and the connection portion 160. In the exemplary implementation shown in FIG. 6, in the operation of transferring the semiconductor element C through the transfer apparatus 100′, the operation of imaging the exterior of the semiconductor element C through the camera unit 150 is not performed.

As shown in FIG. 6, the operation or method of transferring the semiconductor element C through the transfer apparatus 100′ may include an operation of aligning the semiconductor element C and the adsorption portion 120 and lowering the transfer apparatus 100′ toward the semiconductor element C; an operation of vacuum-adsorbing and transferring the semiconductor element C; and an operation of disposing the semiconductor element C in a transfer position, releasing the vacuum adsorption, and raising the transfer apparatus 100′. FIG. 6 illustrates the aforementioned operations in order from left to right.

The transfer operation shown in FIG. 6 may be substantially the same as the transfer operation described above with reference to FIG. 5 except that the operation of imaging the exterior of the semiconductor element C using the camera unit 150 is not performed. Hereinafter, a redundant description will be omitted and replaced with the previous description.

According to an exemplary implementation in the present disclosure, the warpage of the semiconductor element due to vacuum adsorption may be prevented or reduced by vacuum-adsorbing the semiconductor element through a plurality of adsorption portions located in the edges.

In addition,, by providing the heating plate surrounded by a plurality of adsorption portions and exposed externally, heat may be applied to the semiconductor element in a non-contact manner during the transfer process, thereby reducing heat loss of the semiconductor element, and the process of reheating the semiconductor element may be omitted, thereby improving process efficiency.

While example exemplary implementations have been shown and described above, it will be apparent to those skilled in the art that modifications and variations could be made without departing from the scope of the present disclosure as defined by the appended claims.

What is claimed is:

1. An apparatus for transferring a semiconductor element, the apparatus comprising:
a support base;
a plurality of adsorption portions disposed at a lower surface of the support base;
a vacuum portion coupled to the support base and configured to provide a vacuum to the plurality of adsorption portions to thereby hold the semiconductor element; and
a heating portion coupled to the support base and configured to heat the semiconductor element,
wherein the heating portion comprises a heating plate that is disposed at the lower surface of the support base and surrounded by the plurality of adsorption portions.

2. The apparatus according to claim 1, wherein the heating plate is disposed above the plurality of adsorption portions by a specified height toward the lower surface of the support base.

3. The apparatus according to claim 1, wherein the heating plate is configured to be spaced apart from the semiconductor element by a specified distance based on the semiconductor element being in contact with the plurality of adsorption portions.

4. The apparatus according to claim 1, wherein the heating portion is connected to the support base and passes through at least a portion of the support base, and
wherein the heating plate is exposed through the lower surface of the support base.

5. The apparatus according to claim 4, wherein the heating portion further comprises a main body, the main body comprising the heating plate disposed at a lower portion thereof, and
wherein at least a portion of the main body passes through the support base.

6. The apparatus according to claim 1, wherein the heating portion comprises an infrared heater.

7. The apparatus according to claim 1, wherein the heating plate is disposed at a center of the lower surface of the support base, and
wherein the plurality of adsorption portions comprise three or more adsorption portions that surround the heating plate.

8. The apparatus according to claim 1, wherein the plurality of adsorption portions are spaced apart from one another, the plurality of adsorption portions comprising a first adsorption portion, a second adsorption portion, a third adsorption portion, and a fourth adsorption portion that surround the heating plate.

9. The apparatus according to claim 8, wherein the first adsorption portion, the second adsorption portion, the third adsorption portion, and the fourth adsorption portion are arranged symmetrically with respect to the heating plate.

10. The apparatus according to claim 8, wherein each of the first adsorption portion, the second adsorption portion, the third adsorption portion, and the fourth adsorption portion is disposed between an edge portion of the lower surface of the support base and an edge portion of the heating plate.

11. The apparatus according to claim 1, wherein the plurality of adsorption portions are made of a flexible material.

12. The apparatus according to claim 1, wherein each of the plurality of adsorption portions defines an adsorption hole, and
wherein the vacuum portion is connected to the adsorption hole of each of the plurality of adsorption portions through the support base, the vacuum portion being configured to provide the vacuum to the adsorption hole of each of the plurality of adsorption portions.

13. The apparatus according to claim 1, further comprising a camera connected to the support base or the heating portion.

14. The apparatus according to claim 13, further comprising a connection portion that connects the camera to the support base or the heating portion.

15. The apparatus according to claim 1, wherein the apparatus is configured to operate the heating portion while moving the support base toward the semiconductor element before operating the vacuum portion.

16. A method of transferring a semiconductor element, the method comprising:
aligning a transfer apparatus, the transfer apparatus including a plurality of adsorption portions and a heating portion;
lowering the transfer apparatus toward the semiconductor element;
operating the heating portion while lowering the transfer apparatus toward the semiconductor element to thereby satisfy a temperature condition for the semiconductor element;
providing a vacuum to the plurality of adsorption portions to thereby hold the semiconductor element; and
transferring the semiconductor element to a transfer position, releasing the vacuum from the plurality of adsorption portions, and raising the transfer apparatus from the semiconductor element.

17. The method according to claim 16, wherein the transfer apparatus further includes a camera,
wherein the method further comprises:
aligning the semiconductor element and the camera, and
imaging the semiconductor element using the camera.

18. The method according to claim 17, wherein imaging the semiconductor element is performed at least one of (i) before lowering the transfer apparatus to the semiconductor element or (ii) after releasing the vacuum from the plurality of adsorption portions and raising the transfer apparatus from the semiconductor element.

19. The method according to claim 17, wherein the transfer apparatus further includes a support base,
wherein the plurality of adsorption portions are disposed at a lower surface of the support base, and
wherein the heating portion comprises a heating plate disposed at the lower surface of the support base and surrounded by the plurality of adsorption portions.

20. The method according to claim 19, wherein providing the vacuum to the plurality of adsorption portions is performed to bring the semiconductor element in contact with the plurality of adsorption portions, and
wherein transferring the semiconductor element is performed based on the semiconductor element being in contact with the plurality of adsorption portions and spaced apart from the heating plate at a predetermined distance.
